(19) United States
(12) Patent Application Publication
(10) Pub. No.: US 2022/0112077 A1
(43) Pub. Date: Apr. 14, 2022

(54) MEMS ENCAPSULATION STRUCTURE AND MANUFACTURING METHOD THEREOF

(71) Applicant: NINGBO SEMICONDUCTOR INTERNATIONAL CORPORATION (SHANGHAI BRANCH), Shanghai (CN)

(72) Inventor: Xiaoshan QIN, Ningbo, Zhejiang (CN)

(21) Appl. No.: 17/419,218

(22) PCT Filed: Nov. 5, 2019
(86) PCT No.: PCT/CN2019/115609

§ 371 Date: Jun. 28, 2021

(30) Foreign Application Priority Data
Dec. 27, 2018 (CN) 201811615842.2

(51) Int. Cl. B81B 7/00; B81C 1/00

(52) U.S. Cl. CPC B81B 7/007; B81C 1/00301; B81C 2203/0792; B81B 2207/096; B81B 2207/012

(57) ABSTRACT

A micro-electro-mechanical system (MEMS) package structure and a method of fabricating the MEMS package structure. The MEMS package structure includes a MEMS die (210,220) and a device wafer (100). A control unit and an interconnection structure (300) are formed in the device wafer (100), and a first contact pad (410) is formed on a first surface (100a) of the device wafer. The MEMS die (210,220) includes a closed micro-cavity (221), a second contact pad (201) configured to be coupled to an external electrical signal, and a bonding surface (200a,220a). The MEMS die (210,220) is bonded to the first surface (100a) by a bonding layer (500), in which an opening (510) is formed. The first contact pad (410) is electrically connected to the second contact pad (201), and a rewiring layer (700) is arranged on a surface opposing the first surface (100a). The MEMS package structure allows electrical interconnection between the MEMS die and the device wafer with a reduced package size, compared to those produced by existing integration techniques. In addition, a plurality of MEMS dies of the same or different structures and functions are allowed to be integrated on the same device wafer.

### TECHNICAL FIELD

The present invention relates to the field of semiconductor technology and, in particular, to a micro-electro-mechanical system (MEMS) package structure and a method for fabricating it.

### BACKGROUND

The development of very-large-scale integration (VLSI) is leading to increasing shrinkage of critical dimensions of integrated circuits, imposing more and more stringent requirements on integrated circuit packaging techniques. In the market for MEMS sensor packages, MEMS dies have been widely used in smart phones, fitness wristbands, printers, automobiles, drones, head-mounted VR/AR devices and many other products. Common MEMS dies include, among others, those for pressure sensors, accelerometers, gyroscopes, MEMS microphones, optical sensors and catalytic sensors. A MEMS die is usually integrated with another die using a system in package (SiP) approach to form a MEMS device. Specifically, the MEMS die is usually fabricated on one wafer and integrated with an associated control circuit that is formed on another wafer. Currently, the integration is usually accomplished by either of the following two methods: 1) separately bonding the MEMS die-containing wafer and the control circuit-containing wafer to a single packaging substrate and electrically connecting the MEMS die to the control circuit through wiring the MEMS die-containing wafer and the control circuit-containing wafer to solder pads on the substrate; and 2) directly bonding the MEMS die-containing to control circuit-containing wafer with corresponding solder pads thereof forming electrical connections so as to achieve electrical connections between the control circuit and the MEMS die.

However, the above first integration method requires reserved areas for the solder pads, which are often large and thus unfavorable to miniaturization of the resulting MEMS device. MEMS dies with different functions (or structures) are fabricated generally with different processes, and it is usually only possible to fabricate MEMS dies of the same function (or structure) on a single wafer. Therefore, for the above second integration method, it is difficult to form MEMS dies of different functions on a single wafer using semiconductor processes, and it will be complicated in process, costly and bulky in size of the resulting MEMS device to separately bond wafers containing MEMS dies of different functions to wafers containing respective control circuits and then interconnect them together. Thus, the current integration methods for MEMS dies and the resulting MEMS packages structure still fall short in meeting the requirements of practical applications in terms of size and function integration ability.

### SUMMARY OF THE INVENTION

It is an object of the present invention to provide a MEMS package structure with a reduced size and a method of fabricating such a package structure. It is another object of the present invention to provide a MEMS package structure with enhanced function integration ability.

In one aspect of the present invention, there is provided a MEMS package structure, comprising:

a device wafer having a first surface and a second surface opposite to the first surface, wherein the device wafer has a control unit, a first interconnection structure and a second interconnection structure arranged therein, the first and second interconnection structures electrically connected to the control unit; a first contact pad arranged on the first surface, wherein the first contact pad is electrically connected to the first interconnection structure; a MEMS die bonded to the first surface, wherein the MEMS die comprises a closed micro-cavity, a second contact pad configured to be coupled to an external electrical signal and a bonding surface in opposition to the first surface, the first contact pad electrically connected to a corresponding second contact pad; a bonding layer positioned between the first surface and the bonding surface so as to bond the MEMS die to the device wafer, wherein an opening is formed in the bonding layer; and a rewiring layer arranged on the second surface, wherein the rewiring layer is electrically connected to the second interconnection structure second interconnection structure.

Optionally, the rewiring layer may comprise an input/output connection.

Optionally, a plurality of said MEMS dies may be arranged on the first surface, wherein the MEMS dies are categorized in the same or different types depending on a fabrication process thereof.

Optionally, a plurality of said MEMS dies may be arranged on the first surface, wherein the plurality of MEMS dies are categorized in a same or different types depending on a vacuum level of the micro-cavity thereof.

A plurality of said MEMS dies may be arranged on the first surface, and wherein the plurality of MEMS dies include at least one of: a gyroscope, an accelerometer, an inertial sensor, a pressure sensor, a displacement sensor, an optical sensor and a micro-actuator.

Optionally, the control unit may comprise one or more MOS transistors.

Optionally, the first interconnection structure may comprise a first conductive plug extending through at least a partial thickness of the device wafer and electrically connected to the control unit, the first conductive plug having one end exposed at the first surface so as to be electrically connected to the first contact pad; and wherein the second interconnection structure comprises a second conductive plug extending through at least a partial thickness of the device wafer and electrically connected the control unit, the second conductive plug having one end exposed at the second surface so as to be electrically connected to the rewiring layer.

Optionally, the device wafer may be a grinded wafer.

Optionally, the first contact pad may be electrically connected to the corresponding second contact pad via an electrical bump, and wherein the electrical bump is positioned between the first contact pad and the corresponding second contact pad, and is exposed in the opening.

Optionally, the MEMS package structure may further comprise

an encapsulation layer located on the first bonding surface, wherein the encapsulation layer covers the MEMS die and fills the opening in the bonding layer.

Optionally, the bonding layer may comprise an adhesive material.

Optionally, the adhesive material may comprise a dry film.

Optionally, the micro-cavity may be filled with a damping gas or be vacuumed.

In another aspect of the present invention, there is further provided a method for fabricating a MEMS package structure, comprising:

providing a MEMS die and a device wafer for control of the MEMS die, wherein the device wafer has a first surface configured to bond the MEMS die, and wherein the device wafer has a control unit and a first interconnection structure electrically connected to the control unit formed therein; forming a first contact pad on the first surface, wherein the first contact pad is electrically connected to the first interconnection structure, wherein the MEMS die comprises a closed micro-cavity, a second contact pad configured to be coupled to an external electrical signal and a bonding surface; bonding the MEMS die to the device wafer through a bonding layer positioned between the first surface and the bonding surface, wherein the bonding layer has an opening formed therein, wherein the first contact pad and a corresponding second contact pad are exposed in the opening; establishing an electrical connection between the first contact pad and the corresponding second contact pad; forming a second interconnection structure in the device wafer, wherein the second interconnection structure is electrically connected to the control unit; and forming a rewiring layer on a surface of the device wafer in opposition to the first surface, wherein the rewiring layer is electrically connected to the second interconnection structure.

Optionally, the first interconnection structure may comprise a first conductive plug, and wherein the first conductive plug extends through at least a partial thickness of the device wafer and is electrically connected to each of the control unit and a corresponding first contact pad.

Optionally, the second interconnection structure may comprise a second conductive plug, and wherein the second conductive plug extends through at least a partial thickness of the device wafer and is electrically connected to each of the control unit and the rewiring layer.

Optionally, establishing the electrical connection between the first contact pad and the corresponding second contact pad comprises: forming an electrical bump between the first contact pad and the corresponding second contact pad using an electroless plating process, wherein the electrical bump is exposed in the opening.

Optionally, the method for fabricating a MEMS package structure may further comprise:

forming an encapsulation layer on the first surface, wherein the encapsulation layer covers the MEMS die and fills the opening in the bonding layer.

The MEMS package structure provided in the present invention includes a device wafer and MEMS die. The device wafer has a control unit, a first interconnection structure and a second interconnection structure are arranged therein. The first and second interconnection structures are electrically connected to the control unit. A first contact pad is arranged on the first surface, wherein the first contact pad is electrically connected to the first interconnection structure and the MEMS die. A rewiring layer is arranged on the second surface, wherein the rewiring layer is electrically connected to the second interconnection structure. The first contact pad and the second contact pad are electrically connected. The MEMS package structure allows electrical interconnection between the MEMS die and the device wafer with a reduced package size, compared to those produced by existing integration techniques. Moreover, the MEMS package structure may include a plurality of MEMS dies of the same or different functions and structures. Therefore, in addition to size shrinkage, the MEMS package structure is also improved in terms of function integration ability. Arranging the rewiring layer and the MEMS die on each side of the device wafer is conducive to shrinkage of the MEMS package structure and allows lower rewiring and interconnection design complexity and improved reliability of the MEMS package.

As the MEMS package can be fabricated using the method provided in the present invention, the method can offer the same or similar advantages.

### BRIEF DESCRIPTION OF THE DRAWINGS

FIG. 1 is a schematic cross-sectional view showing a device wafer and a plurality of MEMS dies provided in a method of fabricating a MEMS package structure in accordance with an embodiment of the present invention.

FIG. 2 is a schematic cross-sectional view showing a structure resulting from the formation of a plurality of first contact pads on a first surface in the method of fabricating a MEMS package structure in accordance with an embodiment of the present invention.

FIG. 3 is a schematic cross-sectional view showing a structure resulting from bonding the plurality of MEMS dies to the device wafer using a bonding layer in the method of fabricating a MEMS package structure in accordance with an embodiment of the present invention.

FIG. 4 is a schematic cross-sectional view showing a structure resulting from the formation of electrical bumps in the method of fabricating a MEMS package structure in accordance with an embodiment of the present invention.

FIG. 5 is a schematic cross-sectional view showing a structure resulting from the formation of an encapsulation layer in the method of fabricating a MEMS package structure in accordance with an embodiment of the present invention.

FIG. 6 is a schematic cross-sectional view showing a structure resulting from the formation of second interconnection structures in the method of fabricating a MEMS package structure in accordance with an embodiment of the present invention.

FIG. 7 is a schematic cross-sectional view showing a structure resulting from the formation of rewiring layers in the method of fabricating a MEMS package structure in accordance with an embodiment of the present invention.

In these figures,

100: a device wafer; 100a: a first surface; 100b: a second surface; 101: a substrate; 102: an isolation structure; 103: a first dielectric layer; 104: a second dielectric layer; 210: a first MEMS die; 211: a first micro-cavity; 220: a second MEMS die; 221: a second micro-cavity; 410: a first contact pad; 201: a second contact pad; 220a: a bonding surface; 300: an interconnection structure; 310: a first interconnection structure; 311: a first conductive plug; 320: a second interconnection structure; 321: a second conductive plug; 500: a bonding layer; 510: an opening; 501: an encapsulation layer; 600: an electrical bump; and 700: a rewiring layer.

### DETAILED DESCRIPTION

The present invention will be described below in greater detail by way of particular embodiments with reference to the accompanying drawings. Features and advantages of the invention will be more apparent from the following description. Note that the accompanying drawings are provided in a very simplified form not necessarily drawn to exact scale, and their only intention is to facilitate convenience and clarity in explaining the disclosed embodiments.

In the following, the terms “first”, “second”, and so on may be used to distinguish between similar elements without necessarily implying any particular ordinal or chronological sequence. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Identical components or features may be shown in different accompanying drawings, and not all such components and features are labeled in each drawing for the sake of visual clarity, even if they are readily identifiable in all the drawings.

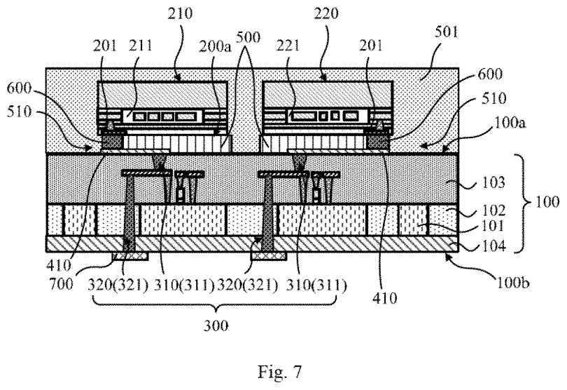

Referring to FIG. 7, a micro-electro-mechanical system (MEMS) package according to an embodiment of the present invention includes:

a device wafer 100 having a first surface 100a and a second surface 100b opposing the first surface 100a, the device wafer 100 has a control unit and an interconnection structure 300 electrically connected to the control unit formed therein; a first contact pad 410 arranged on the first surface 100a, the first contact pad 410 electrically connected to the interconnection structure 300; a MEMS die (e.g., the first MEMS die 210 and/or the second MEMS die 220 of FIG. 7) bonded to the first surface 100a, the MEMS die containing a closed micro-cavity (e.g., the first micro-cavity 211 of the first MEMS die 210 and the second micro-cavity 221 of the second MEMS die 220 shown in FIG. 7), the MEMS die having a second contact pad 201 configured to be coupled to an external electrical signal and a bonding surface 200a in opposition to the first surface 100a, the first contact pad 410 electrically connected to a corresponding second contact pad 201; a bonding layer 500 arranged between the first surface 100a and the bonding surface 200a, which bonds the MEMS die to the device wafer 100, wherein an opening 510 is formed in the bonding layer 500; and a rewiring layer 700 arranged on the second surface 100b, the rewiring layer 700 electrically connected to the interconnection structure 300.

The MEMS package structure may include a plurality of said MEMS dies, which are bonded to the first surface 100a and are driven by, or operate under the control of, respective said control units arranged in the device wafer 100. The device wafer 100 may be formed, for example, by fabricating the plurality of control units in a substrate 101 (e.g., a silicon substrate), using a semiconductor process. The substrate 101 may be, among others, a silicon substrate or a silicon-on-insulator (SOI) substrate. Examples of materials from which the substrate 101 can be fabricated may also include germanium, silicon germanium, silicon carbide, gallium arsenide, indium gallium and other Group III and V compounds. Preferably, the substrate 101 is selected as a substrate allowing relatively easy semiconductor processing or integration. The control units may be formed on the basis of the substrate 101.

Each control unit may include one or more MOS transistors, and in the latter case, adjacent said MOS transistors may be isolated from one another by isolation structure(s) 102 formed in the device wafer 100 (or in the substrate 101) and by an insulating material deposited on the substrate 101. Each isolation structure 102 may be, for example, a shallow trench isolation (STI) and/or deep trench isolation (DTI) structure. As an example, the control unit may control the MEMS die 200 by means of a control electrical signal output from a source/drain of one of the MOS transistor(s). In this embodiment, the device wafer 100 further comprises a first dielectric layer 103 formed on one of the surfaces of the substrate 101, and the source/drain of the control unit for outputting a control electrical signal (i.e., serving as an electrical connection terminal) is arranged in the first dielectric layer 103. On the other surface of the substrate 101, a second dielectric layer 104 is formed. Each of the first and second dielectric layers 103, 104 may be formed of at least one material selected from insulating materials including silicon oxide, silicon nitride, silicon carbide and silicon oxynitride. In this embodiment, the surface of the first dielectric layer 103 away from the substrate 101 may serve as the first surface 100a of the device wafer 100, and the surface of the second dielectric layer 104 away from the substrate 101 may serve as the second surface 100b of the device wafer 100.

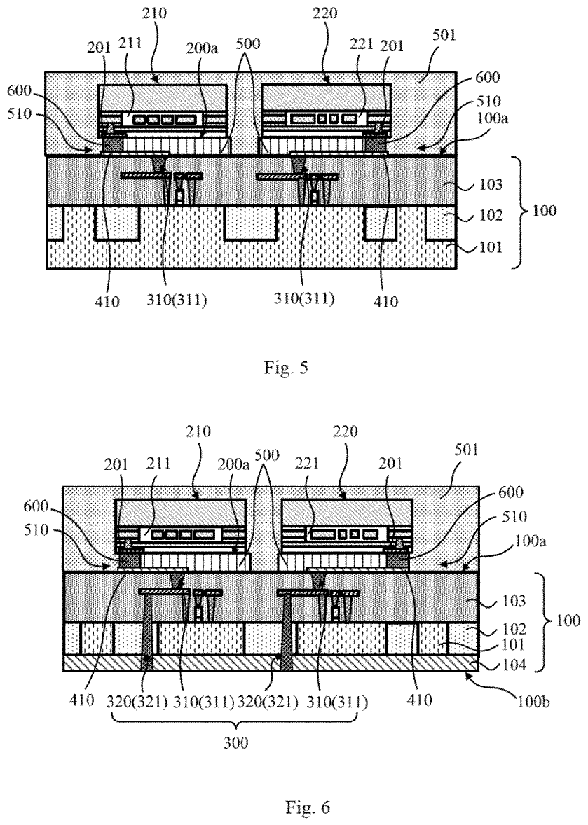

In order to electrically interconnect the MEMS die and the control unit in the device wafer 100, in this embodiment, the interconnection structure 300 is provided in the device wafer 100, which is electrically connected to each of the first contact pad 410 on the first bonding surface 100a, the rewiring layer 700 and the control unit in the device wafer 100. Specifically, referring to FIG. 5, the interconnection structure 300 may include a first interconnection structure 310 for interconnecting the control unit in the device wafer 100 and the first contact pad 410 on the first surface 100a and a second interconnection structure 320 for interconnecting the control unit in the device wafer 100 and the rewiring layer 700 on the second surface 100b.

Each of the first and second interconnection structures 310, 320 may include, formed within the device wafer 100, two or more electrical contacts, electrical connection members and electrical connection lines formed therebetween. Referring to FIG. 7, in this embodiment, the first interconnection structure 310 may include a first conductive plug 311, which penetrates through at least a partial thickness of the device wafer 100 and is electrically connected to corresponding control unit and corresponding first contact pad 410 on the first surface 100a. The second interconnection structure 320 may include a second conductive plug 321, which penetrates through at least a partial thickness of the device wafer 100 and is electrically connected to corresponding control unit and corresponding rewiring layer 700 on the second surface 100b.

This design with the first and second interconnection structures 310, 320 for leading an electrical signal from the control unit to the first and second surfaces 100a, 100b so as to accomplish the connection of the MEMS die with the device wafer 100 and the rewiring thereof on opposing sides of the device wafer 100. This is conducive to shrinkage of the MEMS package structure and allows lower rewiring and interconnection design complexity and improved reliability of the MEMS package.

In order to avoid adversely affecting the control unit in the device wafer 100, each of the first and second conductive plugs 311, 321 is preferably arranged in an isolating material in the device wafer 100. As shown in FIG. 7, the first conductive plug 311 is preferred to extend through a partial thickness of the first dielectric layer 103 to the first surface 100a so that one end of the first conductive plug 311 is exposed at the first surface 100a and electrically connected to the first contact pad 410. In addition, the second conductive plug 321 is preferred to extend through a partial thickness of the first dielectric layer 103 and the isolation structure 102 so that one end of the second conductive plug 321 is exposed at the second surface 100b and electrically connected to the rewiring layer 700. The device wafer 100 is preferably a grinded wafer, which can facilitate the fabrication of the second conductive plug 321 and result in a reduced thickness of the resulting MEMS package structure.

The rewiring layer 700 that is arranged on the second surface 100b of the device wafer 100 and electrically connected to the second interconnection structure 320 may be formed of a conductive material. Specifically, as FIG. 7 shows, the rewiring layer 700 may cover a part of the second conductive plug 321 and thus come into electrical connection with the second interconnection structure 320.

Preferably, the rewiring layer 700 may include a rewiring connection that is electrically connected to the second interconnection structure 320 and an input/output connection for connecting the MEMS package structure to an external signal or device and thus allowing signal processing or control for the connected circuit. Additionally, an input/output connection may be electrically connected to the rewiring connection so that the plurality of input/output connections may process or control a signal input to or output from the MEMS die by the rewiring connection, the second interconnection structure 320 and the control unit.

In case of a plurality of MEMS dies being integrated, they may be of the same or different functions, uses and structures. MEMS dies for various MEMS devices such as gyroscopes, accelerometers, inertial sensors, pressure sensors, displacement sensors, micro-actuators (e.g., micro-motors, micro-resonators, micro-relays, micro-optical/RF switches, optical projection displays, flexible skins, micro-pump/valves) can be fabricated on separate substrates (e.g., silicon wafers) using MEMS die fabrication processes well known in the art and then diced into individual MEMS dies that are taken as the MEMS dies in this embodiment. In practical implementations, depending on the design requirements or the intended use, a number or plurality of MEMS dies of different types may be selected and arranged on the side surface of the device wafer 100 which is used for bonding the MEMS dies. In this embodiment, the first surface 100a of the device 100 is used for bonding the MEMS die, without limitation, in another embodiment, the second surface 100b of the device 100 may also be used for bonding the MEMS die.

MEMS dies with one or more sensing properties can be bonded on the device wafer 100 to increase the functions of the MEMS package structure. As shown in FIG. 7, the first MEMS die 210 is for example a gyroscope, and the second MEMS die 220 is for example an accelerometer. In order to improve the function integration ability of the MEMS package structure, preferably, the above-mentioned multiple MEMS dies belong to the same or different types according to the fabricating process. Here, the fabricating processes of the two types of MEMS dies are not completely the same or the structures are not completely the same. In another embodiment, the multiple MEMS dies belong to the same or different types according to the vacuum level in the corresponding micro-cavity. For example, the ratio of the vacuum level in micro-cavity corresponding to two MEMS dies may be greater than or equal to 10. In yet another embodiment, the plurality of MEMS dies may include at least one of a gyroscope, an accelerometer, an inertial sensor, a pressure sensor, a displacement sensor, and a micro-actuator. According to requirements, the micro-cavity of the MEMS die may also be vacuumed or filled with damping gas.

It is to be understood that while the description of this embodiment focuses on the MEMS package structure including the device wafer 100 and a MEMS die arranged on the first surface 100a thereof, it does not imply that the MEMS package structure of the present embodiment is only made up of these components because the device wafer 100 may be further provided with one or more different chips arranged thereon or bonded thereto (e.g., memory chips, communication chips, processor chips, etc.), one or more different devices arranged thereon (e.g., power devices, bipolar devices, resistors, capacitors, etc.) and/or components and connection means well known in the art. The present invention is not limited to only one MEMS die being bonded to the device wafer 100, as two, three or more MEMS dies can be bonded thereto. In the latter case, structures and/or types of these MEMS dies may vary depending on the actual requirements. In addition, the first contact pads 410 and the second contact pads 220 mentioned in this embodiment may be solder pad or other connecting components for electrical connection.

In this embodiment, the MEMS die(s) (such as the first MEMs die 210 and/or the second MEMS die 220) may be bonded to the first surface 100a of the device wafer 100 by a bonding layer 500 (if a plurality of MEMS dies are present, they may be arranged on the first bonding surface 100a side by side). Specifically, the MEMS die is bonded to the first surface 100a, and the MEMS die may have a closed micro-cavity, a second contact pad 201 for coupling to an external electrical signal and a bonding surface 200a in opposition to the first surface 100a. In addition, the second contact pad 201 of the MEMS die may be electrically connected to an associated first contact pad 410 on the first surface 100a of the device wafer 100, for example, via an electrical bump 600 arranged between the first contact pad 410 and corresponding second contact pad 201. A plurality of electrical bumps 600 may be provided so as to connect second contact pad 201 of each MEMS die to corresponding first contact pad 410.

The bonding layer 500 may be configured to fixedly bond the MEMS dies to the device wafer 100. Specifically, the bonding layer 500 may be arranged between the first surface 100a of the device wafer 100 and the bonding surfaces 200a of the MEMS dies. Openings 510 may be formed in the bonding layer 500, in which the electrical bumps 600 are exposed. As shown in FIG. 7, the openings 510 is oriented to the gap between the plurality of MEMS dies or each side of MEMS die, and a part of the side surface of the electrical bump 600 is exposed in the opening 510.

Examples of suitable materials for the bonding layer 500 may include oxides or other materials. For example, the bonding layer 500 may be a bonding material that bonds the bonding surfaces 200a of the plurality of MEMS dies to the first surface 100a of the device wafer 100 by fusing bonding, vacuum bonding or otherwise. Examples of suitable materials for the bonding layer 500 may also include adhesive materials. In this case, for example, the bonding layer 500 may be a die attach film (DAF) or a dry film, which glues the MEMS dies to the device wafer 100 by adhesion. In this embodiment, the bonding layer 500 is preferably a dry film which is an adhesive photoresist film where a polymerization reaction can take place in the presence of ultraviolet radiation and produce a stable substance that adheres to a surface to be bonded. The dry film has the advantages of electroplating and etching resistance. The dry film may be so applied to the bonding surfaces 200a of the MEMS dies that the second contact pads 201 are exposed from the dry film, allowing the second contact pads 220 to be subsequently electrically connected to the respective first contact pads 410 of the device wafer 100 more easily. The second contact pad 201 of the MEMS die 200 may be arranged, for example, at a location of the bonding surface 200a of the MEMS die that is close to an edge of the bonding surface 200a. In this way, the second contact pads 201 can be exposed when the openings 510 are formed in the bonding layer 500 at the edge of the MEMS die or between the MEMS dies 200.

In this embodiment, the MEMS package structure may further include an encapsulation layer 501 on the first surface 100a of the device wafer 100. The encapsulation layer 501 covers the MEMS dies, fills the openings 510 in the bonding layer 500, and optionally covers other portions of the first surface 100a. The encapsulation layer 501 is provided to more firmly fix the MEMS dies to the device wafer 100 and protect them from external damage. The encapsulation layer 501 may be formed of, for example, a plastic material. For example, an injection molding process may be employed to fill the plastic material in gap(s) between the plurality of MEMS dies and fix the plurality of MEMS dies to the bonding layer 500. The plastic material of the encapsulation layer 501 may be in a softened or flowable form during the molding and may be molded in a predetermined shape. Alternatively, the material of the encapsulation layer 501 may solidify by chemical crosslinking. As an example, the material of the encapsulation layer 501 may include, for example, at least one of thermosetting resins including phenolic resins, urea-formaldehyde resins, formaldehyde-based resins, epoxy resins, polyurethanes and so on. Preferably, the material of the encapsulation layer 501 is selected as an epoxy resin, in which a filler may be added, as well as one or more of various additives (e.g., curing agents, modifiers, mold release agents, thermal color agents, flame retardants, etc.) For example, a phenolic resin may be added as a curing agent and a micro-powder consisting of solid silicon particles as a filler.

The MEMS package structure allows electrical interconnection between the MEMS die(s) and the device wafer 100 with a reduced package size, compared to those produced by existing integration techniques. In addition, a plurality of MEMS dies of the same or different functions (uses) and structures are allowed to be integrated on the same device wafer 100. Therefore, in addition to size shrinkage, the MEMS package structure is also improved in terms of function integration ability.

In embodiments of the present invention, there is provided a method for fabricating a MEMS package structure as defined above. Steps for fabricating the MEMS package structure are as follows:

step 1: providing a MEMS die and a device wafer for control of the MEMS die; the device wafer has a first surface, to which the MEMS die is to be bonded. A control unit and a first interconnection structure electrically connected to the control unit are formed in the device wafer.

step 2: forming a first contact pad on the first surface, which is electrically connected to the first interconnection structure; the MEMS die includes a closed micro-cavity, a second contact pad for coupling to an external electrical signal and a bonding surface.

step 3: bonding the MEMS die to the device wafer by a bonding layer arranged between the first surface and the bonding surface; an opening is formed in the bonding layer, in which the first contact pad and the second contact pad are exposed.

step 4: establishing an electrical connection between the first and second contact pads.

step 5: forming a second interconnection structure in the device wafer, which is electrically connected to the control unit.

step 6: forming a rewiring layer on the surface of the device wafer opposing the first surface, which is electrically connected to the second interconnection structure.

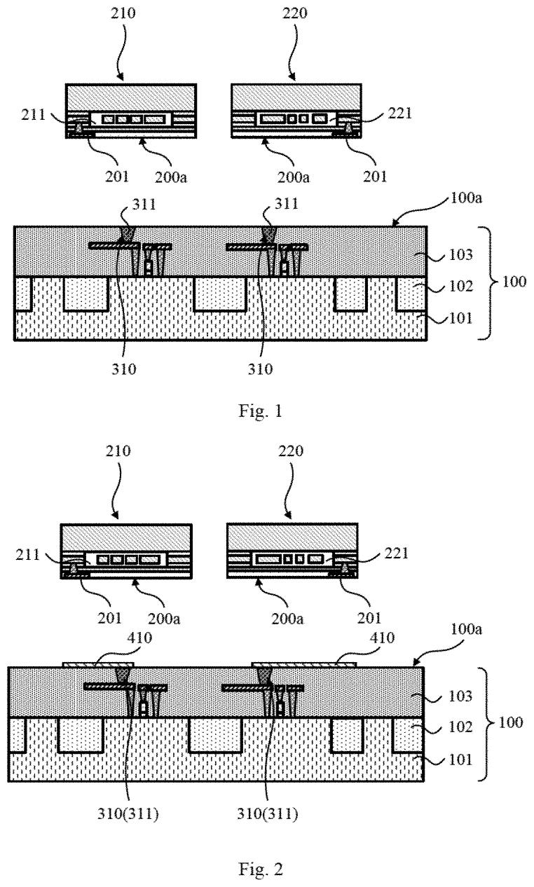

A more detailed process for fabricating a MEMS package structure in accordance with embodiments of the present invention will be described with reference to FIGS. 1 to 7.

FIG. 1 is a schematic cross-sectional view showing a device wafer and a plurality of MEMS dies provided in a method for fabricating a MEMS package structure in accordance with an embodiment of the present invention. Referring to FIG. 1, in step 1, the MEMS dies and the device wafer 100 for control of the plurality of MEMS dies are provided. The device wafer 100 has a first surface 100a, to which the MEMS dies are to be bonded. Control units and first interconnection structures 310 electrically connected to the control units are formed in the device wafer 100. In this embodiment, the device wafer 100 is generally in the shape of a flat plate, and the plurality of control units may be arranged side by side in the device wafer 100 and be interconnected according to the position of the MEMS die.

In this embodiment, instead of only one MEMS die, two or more MEMS dies may be integrated on the device wafer 100. As an example shown in FIG. 1, the plurality of MEMS dies include a first MEMS die 210 and a second MEMS die 220; the first MEMS die 210 has a first micro-cavity 211, and the second MEMS die 220 has a second micro-cavity 221; each of the first micro-cavity 211 and the second micro-cavity 221 is closed; in addition, each of the first and second MEMS dies 210, 220 has a second contact pad 201 for connecting to external electrical signal and a bonding surface 200a for bonding the device wafer 100.

Specifically, in this embodiment, the device wafer 100 may include a substrate 101, which is a silicon substrate or silicon-on-insulator (SOI) substrate, for example. The plurality of control units may be formed on the basis of the substrate 101 using an established semiconductor process in order to subsequently control the respective MEMS dies. Each control unit may consist of a set of CMOS control circuits. For example, each control unit may include one or more MOS transistors, and in the latter case, adjacent said MOS transistors may be isolated from one another by isolation structure(s) 102 formed in the substrate 101 (or in the device wafer 100) and by an insulating material deposited on the substrate 101. Each isolation structure 102 may be, for example, a shallow trench isolation (STI) and/or deep trench isolation (DTI) structure. The device wafer 100 may further include a first dielectric layer 103 on one surface of the substrate 101, and a connection terminal of each control unit for outputting a control electrical signal may be arranged in the first dielectric layer 103. Without limitation, in this embodiment, the surface of the first dielectric layer 103 away from the substrate 101 may serve as the first surface 100a of the device wafer 100. In another embodiment, the MEMS dies may be bonded to another surface of the device wafer 100. The device wafer 100 may be fabricated using a method known in the art.

Each first interconnection structure 310 may include, formed within the device wafer 100, two or more electrical contacts, electrical connection members and electrical connection lines therebetween. In this embodiment, each first interconnection structure 310 in the device wafer 100 may include a first conductive plug 311 (i.e., a plurality of such first conductive plugs 311 in case of a plurality of MEMS dies being integrated), which penetrates through at least a partial thickness of the device wafer 100 and is electrically connected to the control unit in the device wafer 100. The first conductive plug 311 may be formed of a conductive material selected as a metal or alloy containing cobalt, molybdenum, aluminum, copper, tungsten or the like, or as a metal silicide (e.g., titanium silicide, tungsten silicide, cobalt silicide, or the like), a metal nitride (e.g., titanium nitride), doped polysilicon, or the like. In this embodiment, the material of the first conductive plug 311 is selected as copper, and the end face of the first conductive plug 311 close to the first surface 100a of the device wafer 100 is processed by a copper CMP process so as to be flush with the first surface 100a.

The plurality of MEMS dies may be of the same or different functions, uses or structures. In this embodiment, in order for the MEMS package structure to be versatile or multi-functional, the MEMS dies to be integrated are preferably of two or more different types. For example, the MEMS dies may be at least two selected from those for a gyroscope, an accelerometer, an inertial sensor, a pressure sensor, a flow sensor, a displacement sensor and a micro-actuator; or at least two selected from those for an electric field sensor, an electric field intensity sensor, a magnetic flux sensor and a magnetic intensity sensor. In this embodiment, each MEMS die may be an independent chip (or die). The second contact pad 201 of each MEMS die may be located on the second bonding surface 200a of corresponding MEMS dies, for example, at a location close to an edge of the second bonding surface 200a. This can facilitate exposure of the second contact pad 220 when an opening 510 is subsequently formed in the bonding layer 500 between the MEMS dies. However, the present invention is not limited thereto, because depending on how the MEMS die is wired, the second contact pad 201 may also be arranged at another location on the surface of the MEMS die.

Within the micro-cavity of the MEMS die, there may be a high- or low-vacuum environment or filled with a damping gas. It can be understood that although only two MEMS dies are shown in FIG. 1, the manufacturing method of the MEMS package structure of this embodiment can also be applied to a situation including one or more than two MEMS dies. The MEMS dies may be fabricated using techniques known in the art.

FIG. 2 is a schematic cross-sectional view showing a structure resulting from the formation of a plurality of first contact pads on a first surface in the method of fabricating a MEMS package structure in accordance with an embodiment of the present invention. Referring to FIG. 2, in step 2, the first contact pads 410 are formed on the first surface 100a, which are electrically connected to the respective first interconnection structure 310.

In case of a plurality of MEMS dies being integrated, a plurality of said first contact pads 410 may be formed using the same film-forming and patterning process. For example, a metal layer may be deposited on the first surface 100a of the device wafer 100. The metal layer may be formed of the same material or material with similar conductive functions as that of the first conductive plug 311 by physical vapor deposition (PVD), atomic layer deposition (ALD) or chemical vapor deposition (CVD) and then patterned to form the first contact pads 410. The first contact pads 410 are electrically connected to the respective first interconnection structures 310 to allow external connection of electrical signals from the control units. Depending on the design requirements, in case of a plurality of MEMS dies being integrated, a plurality of first contact pads 410 may be formed on the first surfaces 100a and electrically interconnected.

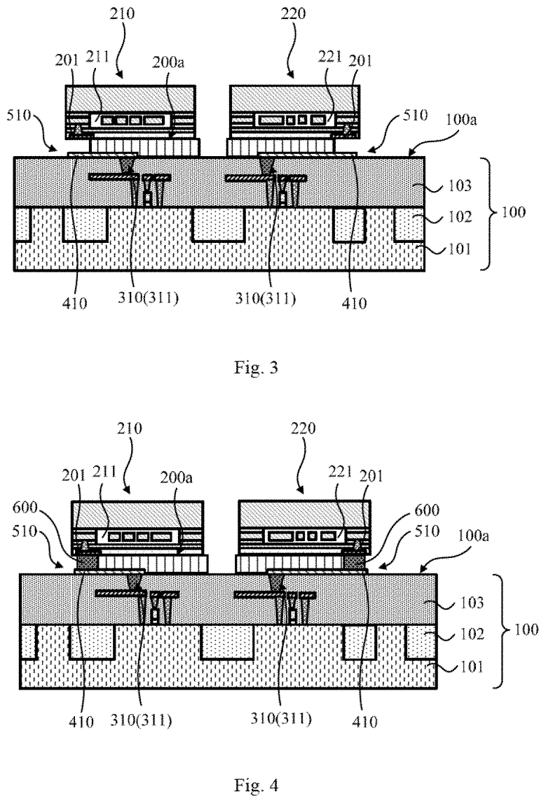

FIG. 3 is a schematic cross-sectional view showing a structure resulting from bonding the plurality of MEMS dies to the device wafer using a bonding layer in the method of fabricating a MEMS package structure in accordance with an embodiment of the present invention. Referring to FIG. 3, the MEMS dies are bonded to the device wafer 100 using the bonding layer 500 positioned between the first surface 100a and the respective bonding surface 500. Openings 510 are formed in the bonding layer 500, in which the first contact pads 410 and the second contact pads 201 of corresponding MEMS die are exposed.

Optionally, the bonding of the MEMS dies to the device wafer 100 may be accomplished with, for example, a fusing bonding process or vacuum bonding process. In this case, the bonding layer 500 may be formed of a bonding material (e.g., silicon oxide). Alternatively, the bonding of the MEMS dies to the device wafer 100 may be accomplished by both a bonding process and a light (or thermal) curing process. In this case, the bonding layer 500 may include an adhesive material, in particular, a die attach film or a dry film. The plurality of MEMS dies may be bonded one by one, or the plurality of MEMS dies may be transferred to one or more carrier plates and then bonded onto the device wafer 100 at the same time or in batches.

In an optional embodiment, during the bonding of the MEMS dies to the device wafer 100, the bonding material may be applied only to intended locations of the device wafer 100 such that the second contact pads 201 and the corresponding first contact pads 410 remain exposed, thus resulting in the formation of the openings 510 in the bonding layer 500. In an alternatively embodiment, during the bonding of the MEMS dies to the device wafer 100, the bonding material may be applied to both the first surface 100a of the device wafer 100 and the bonding surfaces 200a of the MEMS dies, followed by the formation of the openings 510 in which the second contact pads 201 and the respective first contact pads 410 are exposed, for example, using a dry etching process. The openings 510 in the bonding layer 500 are formed in order to enable connection of the first contact pads 410 connected to the control units in the device wafer 100 to the respective second contact pads 201 in the MEMS dies between the first surface 100a and the bonding surface 200a.

FIG. 4 is a schematic cross-sectional view showing a structure resulting from the formation of electrical bumps in the method of fabricating a MEMS package structure in accordance with an embodiment of the present invention. Referring to FIG. 4, in step 4, electrical connections are established between the first contact pads 410 and the respective second contact pads 201.

In this embodiment, the first contact pads 410 and the respective second contact pad 201 are exposed in the openings 510 formed in the bonding layer 500, and electrical bumps 600 may be formed between the first and second contact pads 410, 201 to connect them together. The electrical bumps 600 may be so formed that they do not fill up the openings 510 and are thus exposed therein.

The formation of the electrical bumps 600 may be accomplished using an electroless plating involving, for example, placing the device wafer 100 with the plurality of MEMS dies bonded thereon and with the openings 510 formed in the bonding layer 500 into a solution containing metal ions (e.g., a solution for electroless plating of silver, nickel, copper or the like), where the metal ions are reduced by a strong reducing agent into the corresponding metal which is deposited onto the first contact pads 410 and the respective second contact pads 201 exposed in the openings 510. After the lapse of a certain length of time, the metal connects the first contact pad 410 to the respective second contact pads 201, thus resulting in the formation of the electrical bumps 600. Examples of suitable materials for the electrical bumps 600 may include one or more of copper, nickel, zinc, tin, silver, gold, tungsten and magnesium. The electroless plating process may further involve, before the placement into the solution containing metal ions, depositing a seed layer at intended locations in the openings 510 where the electrical bumps 600 are to be formed.

Forming the electrical bumps 600 between the first surface 100a and the bonding surfaces 200a enables electrical connection between the first contact pads 410 and the respective second contact pads 201 without the need for wire bonding. This is conducive to size shrinkage of the MEMS package structure and can improve its reliability by not affecting the inside of the device wafer 100.

FIG. 5 is a schematic cross-sectional view showing a structure resulting from the formation of an encapsulation layer in the method of fabricating a MEMS package structure in accordance with an embodiment of the present invention. Referring to FIG. 5, subsequent to formation of the electrical bump 600 in opening 510, in order to protect the MEMS dies on the device wafer 100 from external factors (e.g., moisture, oxygen, vibration, shock, etc.) and fix them more firmly, in this embodiment, subsequent to the formation of the electrical bumps 600, this method further comprises: forming the encapsulation layer 501 on the first surface 100a, which covers the plurality of MEMS dies and fills the openings 510 in the bonding layer 500.

Examples of suitable materials for the encapsulation layer 501 may include: inorganic insulating materials, such as silicon oxide, silicon nitride, silicon carbide, silicon oxynitride, etc.; thermoplastic resins, such as polycarbonate, polyethylene terephthalate, polyethersulfone, polyphenylether, polyamides, polyetherimides, methacrylic resins, cyclic polyolefin based resins, etc.; thermosetting resins, such as epoxy resins, phenolic resins, urea-formaldehyde resins, formaldehyde-based resins, polyurethanes, acrylic resins, vinyl ester resins, imide based resins, urea resins, melamine resins, etc.; and organic insulating materials, such as polystyrene, polyacrylonitrile, etc. The encapsulation layer 501 may be formed using, for example, a chemical vapor deposition process or an injection molding process. Preferably, the formation of the encapsulation layer 501 further involves a planarization process performed on the side of the device wafer 100 with the bonding layer 500 so as to make the top surface of the encapsulation layer flat (e.g., parallel to the first surface 100a) so that the planarized encapsulation layer 501 may provide support for the subsequent formation of the rewiring layers on the side opposing the first surface 100a.

FIG. 6 is a schematic cross-sectional view showing a structure resulting from the formation of second interconnection structures in the method of fabricating a MEMS package structure in accordance with an embodiment of the present invention. Referring to FIG. 6, in step 5, the second interconnection structures 320 electrically connected to the control units of the device wafer 100 are formed in the device wafer 100.

In order to reduce the size of the MEMS package structure, in this embodiment, prior to the formation of the second interconnection structures, the device wafer 100 may thinned from the thickness direction thereof in opposition to the first surface 100a. In particular, the thinning may be accomplished with a back-grinding process, a wet etching process or a hydrogen ion implantation process. In this embodiment, the substrate 101 may be thinned from the side thereof opposing the first surface 100a until it becomes flush with the isolation structures 102 therein.

In order to optimize the thinned side with enhanced adhesion of the subsequently formed rewiring layers and reduced surface defects, subsequent to the thinning of the substrate 101, a dielectric material may be deposited onto the thinned surface of the device wafer 100, thus resulting in the formation of a second dielectric layer 104, as shown in FIG. 6. The resulting second dielectric layer 104 may cover the thinned surface of the device wafer 100. For convenience, the surface of the second dielectric layer 104 away from the first surface 100a of the device wafer 100 can be considered as the second surface 100b of the device wafer 100. It is to be understood that although the device wafer 100 is shown in a non-flipped configuration throughout the figures in order to better demonstrate the correspondence of the illustrated structures to the described steps, in this embodiment, the device wafer 100 may be flipped over during the thinning and subsequent processes with the surface of the encapsulation layer 501 away from the first surface 100a as a support surface.

Each second interconnection structure 320 may include two or more electrical contacts, electrical connection members and electrical connection lines each connecting any two of the above, which are all formed in the device wafer 100. In this embodiment, each second interconnection structure 320 includes a second conductive plug 321 (i.e., a plurality of such second conductive plugs 321 in case of a plurality of MEMS dies being integrated) formed in the device wafer 100. The second conductive plug 321 extends through at least a partial thickness of the device wafer 100 and is electrically connected to a respective one of the control units. In addition, the second conductive plug 320 is exposed at one end at the second surface 100b so as to be connected to a respective one of the subsequently formed rewiring layers. Preferably, each second interconnection structure 320 extends through an isolation structure 102 in the device wafer 100 in order to avoid adversely affecting the respective control unit. The first and second plugs 310, 320 may be fabricated using any suitable method known in art, and a description thereof will be omitted herein for the sake of brevity. Such first and second interconnection structures 310, 320 may form the interconnection structure 300 in the device wafer 100.

FIG. 7 is a schematic cross-sectional view showing a structure resulting from the formation of rewiring layers in the method of fabricating a MEMS package structure in accordance with an embodiment of the present invention. Referring to FIG. 7, in step 6, the rewiring layers 700 which are electrically connected to the second interconnection structures 320 are formed on the surface of the device wafer 100 opposing the first surface 100a (i.e., the second surface 100b of FIG. 7).

Specifically, the rewiring layers 700 may reside on the second dielectric layer 104 and come into contact with the second conductive plugs 320 so as to be electrically connected to the second interconnection structures 320. For example, a metal layer may be deposited by physical vapor deposition (PVD), atomic layer deposition (ALD) or chemical vapor deposition (CVD) over the second surface 100b of the device wafer 100 and then patterned to form the rewiring layers 700. Depending on the design requirements, the resulting rewiring layers 700 may include rewiring connections which lead out the electrical contacts for the MEMS dies and thus enable electrical interconnection between the MEMS dies and the device wafer 100 and between the MEMS dies themselves. The rewiring layers 700 may further include input/output connections (not shown) configured to connect the MEMS packages structure to external signals or devices and thus allow signal processing or control for the connected circuits.

After the above steps, the MEMS package structure resulting from the method of fabricating a MEMS package structure according to the above embodiment is shown in FIG. 7. A plurality of MEMS dies are integrated on the same device wafer 100, with rewiring layers 700 being formed on the side of the device wafer 100 opposite to the MEMS dies. This allows a reduced package structure size, compared with those produced by existing integration techniques. In addition, the plurality of MEMS dies integrated on the same device wafer may be of the same or different functions (uses) and structures. Therefore, in addition to size shrinkage, the MEMS package structure is also improved in terms of function integration ability. Arranging the rewiring layer and the MEMS die on opposing sides of the device wafer is conducive to shrinkage of the MEMS package structure and allows lower rewiring and interconnection design complexity and improved reliability of the MEMS package structure. This is helpful in addressing the requirements of practical applications in terms of integration, portability and performance of MEMS packages structure containing MEMS dies.

Described above are some several preferred embodiments of the present invention, which are not intended to limit the present invention in any sense. In light of the principles and teachings hereinabove, any person of skill in the art may make various possible variations and changes to the disclosed embodiments, without departing from the scope of the invention. Accordingly, any and all such simple variations, equivalent alternatives and modifications made to the foregoing embodiments without departing from the scope of the invention are intended to fall within the scope thereof.

What is claimed is:

1. A micro-electro-mechanical system (MEMS) package structure, comprising:
a device wafer having a first surface and a second surface opposite to the first surface, wherein the device wafer has a control unit, a first interconnection structure and a second interconnection structure arranged therein, the first and second interconnection structures electrically connected to the control unit;
a first contact pad arranged on the first surface, wherein the first contact pad is electrically connected to the first interconnection structure;
a MEMS die bonded to the first surface, wherein the MEMS die comprises a closed micro-cavity, a second contact pad configured to be coupled to an external electrical signal and a bonding surface in opposition to the first surface, the first contact pad electrically connected to a corresponding second contact pad;
a bonding layer positioned between the first surface and the bonding surface so as to bond the MEMS die to the device wafer, wherein an opening is formed in the bonding layer; and
a rewiring layer arranged on the second surface, wherein the rewiring layer is electrically connected to the second interconnection structure.

2. The MEMS package structure of claim 1, wherein the rewiring layer comprises an input/output connection.

3. The MEMS package structure of claim 1, wherein a plurality of MEMS dies are arranged on the first surface, and wherein the plurality of MEMS dies are categorized in a same or different types depending on a fabrication process thereof.

4. The MEMS package structure of claim 1, wherein a plurality of MEMS dies are arranged on the first surface, wherein the plurality of MEMS dies are categorized in a same or different types depending on a vacuum level of the micro-cavity thereof.

5. The MEMS package structure of claim 1, wherein a plurality of MEMS dies are arranged on the first surface, and wherein the plurality of MEMS dies include at least one of: a gyroscope, an accelerometer, an inertial sensor, a pressure sensor, a displacement sensor, an optical sensor and a micro-actuator.

6. The MEMS package structure of claim 1, wherein the control unit comprises one or more MOS transistors.

7. The MEMS package structure of claim 1, wherein the first interconnection structure comprises a first conductive plug extending through at least a partial thickness of the device wafer and electrically connected to the control unit, the first conductive plug having one end exposed at the first surface so as to be electrically connected to the first contact pad; and wherein the second interconnection structure comprises a second conductive plug extending through at least a partial thickness of the device wafer and electrically connected the control unit, the second conductive plug having one end exposed at the second surface so as to be electrically connected to the rewiring layer.

8. The MEMS package structure of claim 1, wherein the device wafer is a grinded wafer.

9. The MEMS package structure of claim 1, wherein the first contact pad is electrically connected to the corresponding second contact pad via an electrical bump, and wherein the electrical bump is positioned between the first contact pad and the corresponding second contact pad, and is exposed in the opening.

10. The MEMS package structure of claim 1, further comprising
an encapsulation layer located on the first bonding surface, wherein the encapsulation layer covers the MEMS die and fills the opening in the bonding layer.

11. The MEMS package structure of claim 1, wherein the bonding layer comprises an adhesive material.

12. The MEMS package structure of claim 11, wherein the adhesive material comprises a dry film.

13. The MEMS package structure of claim 1, wherein the micro-cavity is filled with a damping gas or is vacuumed.

14. A method for fabricating a micro-electro-mechanical system (MEMS) package structure, comprising:
providing a MEMS die and a device wafer for control of the MEMS die, wherein the device wafer has a first surface configured to bond the MEMS die, and wherein the device wafer has a control unit and a first interconnection structure electrically connected to the control unit formed therein;
forming a first contact pad on the first surface, wherein the first contact pad is electrically connected to the first interconnection structure, wherein the MEMS die comprises a closed micro-cavity, a second contact pad configured to be coupled to an external electrical signal and a bonding surface;
bonding the MEMS die to the device wafer through a bonding layer positioned between the first surface and the bonding surface, wherein the bonding layer has an opening formed therein, wherein the first contact pad and a corresponding second contact pad are exposed in the opening;
establishing an electrical connection between the first contact pad and the corresponding second contact pad;
forming a second interconnection structure in the device wafer, wherein the second interconnection structure is electrically connected to the control unit; and
forming a rewiring layer on a surface of the device wafer in opposition to the first surface, wherein the rewiring layer is electrically connected to the second interconnection structure.

15. The method for fabricating a MEMS package structure of claim 14, wherein the first interconnection structure comprises a first conductive plug, and wherein the first conductive plug extends through at least a partial thickness of the device wafer and is electrically connected to each of the control unit and a corresponding first contact pad.

16. The method for fabricating a MEMS package structure of claim 14, wherein the second interconnection structure comprises a second conductive plug, and wherein the second conductive plug extends through at least a partial thickness of the device wafer and is electrically connected to each of the control unit and the rewiring layer.

17. The method for fabricating a MEMS package structure of claim 14, wherein establishing the electrical connection between the first contact pad and the corresponding second contact pad comprises: forming an electrical bump between the first contact pad and the corresponding second contact pad using an electroless plating process, wherein the electrical bump is exposed in the opening.

18. The method for fabricating a MEMS package structure of claim 17, further comprising, subsequent to forming the electrical bump and prior to forming the second interconnection structure:
forming an encapsulation layer on the first surface, wherein the encapsulation layer covers the MEMS die and fills the opening in the bonding layer.
